(19) United States
(12) Patent Application Publication
(10) Pub. No.: US 2013/0113103 A1
(43) Pub. Date: May 9, 2013

(54) DEVICE HAVING TSVs WITH GETTERING LAYER LATERAL TO TSV TIPS

(71) Applicants: JEFFREY A. WEST, DALLAS, TX (US); RAJESH TIWARI, PLANO, TX (US)

(72) Inventors: JEFFREY A. WEST, DALLAS, TX (US); RAJESH TIWARI, PLANO, TX (US)

(73) Assignee: TEXAS INSTRUMENTS INCORPORATED, Dallas, TX (US)

(21) Appl. No.: 13/489,219

(22) Filed: Jun. 5, 2012

Related U.S. Application Data
(60) Provisional application No. 61/555,017, filed on Nov. 3, 2011.

(51) Int. Cl. H01L 23/532; H01L 21/302

(52) U.S. Cl. 257/751; 438/476; 257/E23.161; 257/E21.214

(57) ABSTRACT

An integrated circuit (IC) includes a substrate having a topside semiconductor surface including active circuitry configured to provide functionality and a bottomside surface. A plurality of through substrate vias (TSVs) extend from the topside semiconductor surface to beyond the bottomside surface to provide protruding TSV tips. The TSVs include an outer dielectric liner, a metal comprising diffusion barrier layer on the dielectric liner, and a metal filler on the metal comprising barrier layer. A dielectric metal gettering layer (MGL) is on the bottomside surface lateral to and on sidewalls of the protruding TSV tips. The MGL includes at least one metal gettering agent selected from a halogen or a Group 15 element in an average concentration from 0.1 to 10 atomic %.

### CROSS REFERENCE TO RELATED APPLICATIONS

This application claims the benefit of Provisional Application Ser. No. 61/555,017 entitled “Method and Structure for achieving ionic decontamination resulting from TSV Tip Reveal processing” filed Nov. 3, 2011, which is herein incorporated by reference in its entirety.

### FIELD

Disclosed embodiments relate to integrated circuit (IC) devices having through-substrate vias that include a metal filler, a metal barrier and a dielectric liner, where the TSVs include TSV tips.

### BACKGROUND

As known in the art, through-substrate vias (referred to herein as TSVs), which are commonly referred to as through-silicon vias, are vertical electrical connections which extend from one of the electrically conductive levels formed on the topside semiconductor surface of the IC die (e.g., one of the metal interconnect levels) to the bottomside surface of the IC die. TSVs are used as power TSVs (e.g., for VDD, VSS or ground) and/or signal TSVs. Signal TSVs are generally formed close to active circuitry which includes transistors, such as within 5 to 20 μm from the active circuitry. The TSV planar (x-y) dimensions can be about 5 to 50 μm, with aspect ratios (ARs) from about 5:1 to 20:1.

TSVs allow the IC to be bonded to on both sides and utilize vertical electrical paths to couple to other IC devices (e.g., to another die, or wafer), or to mount to a package substrate positioned below the IC die. The vertical electrical paths are significantly shortened relative to conventional wire bonding technology, generally leading to significantly faster device operation of the IC.

TSVs can be formed using processes including “via-first,” a “via-middle,” or a “via-last” approach. In the via-first approach the TSVs are formed in the wafer fab during front end processing. Via-first can comprise TSV formation before transistors are formed. Via-middle can take place after transistor formation, such as formed between the contact level and first metal, or after one or more levels of metal interconnect, but before passivation. In contrast, the via-last approach takes place in assembly and packaging and typically forms the TSVs from the bottomside surface of the IC die after wafer processing is completed (i.e. after passivation processing). An alternate process is trench-first—via-last, where the isolation zone (typically an annulus filled with SiO₂, SiN, or their combination) is created before the front end of the line (FEOL) processing, then after wafer thinning, a TSV is created from the bottomside of the wafer within each isolation zone.

In a typical via-first or via-middle process, vias are formed to a depth (e.g., 10 μm to 300 μ) that is less than the full wafer thickness (e.g., 400 μm to about 775 μm for 12 inch wafers) using chemical etching, laser drilling, or one of several energetic methods, such as Reactive Ion Etching (RIE). Once the vias are formed, they are generally framed with a dielectric liner to provide electrical isolation from the surrounding semiconductor substrate. The dielectric liner is generally formed from silicon oxide, silicon nitride, or silicon oxynitride.

The vias are then made electrically conductive by filling the vias with an electrically conductive filler (or core) material (e.g., copper, tungsten or doped polysilicon) to form embedded TSVs. The bottom of the embedded TSV may be referred to as an embedded TSV tip. In the case the electrically conductive filler materials comprises a metal, some metals (e.g., copper) are known to provide band gap states near the center of the semiconductor's band gap. As a result, such metals if highly mobile in the semiconductor can significantly degrade minority carrier lifetimes in the semiconductor, and cause problems such as increased junction leakage or a shift in metal-oxide-semiconductor (MOS) transistor threshold voltage.

To prevent escape of the filler metal into the surrounding semiconductor, a diffusion barrier layer is generally deposited on the dielectric liner. The diffusion barrier layer generally comprises refractory-metal comprising materials such as titanium (Ti), titanium nitride (TiN), tantalum (Ta), tantalum nitride (TaN), or ruthenium (Ru). Such diffusion barrier layer layers are known to be effective against diffusion of most metals, including copper.

For via-first and via-middle processes, a backgrinding/polishing step is conventionally used to thin the wafer by removing a sufficient thickness of the substrate (e.g., 500 μm to 740 μm) from the bottomside surface of the wafer to reach the embedded TSV filler material to expose the electrically conductive filler material at the distal end of the TSV tip. Grinding/polishing to reach the TSV tips is desirable for achieving optimum within-die tip coplanarity and across-wafer (die-to-die) tip protrusion height uniformity. Grinding/polishing also achieves high wafer throughput.

However, grinding/polishing to expose/reveal TSV tips can cause smearing across the bottomside of the wafer or chemical dispersal of the filler material into the immediate aqueous solution. Smearing and dispersal are both thus prone to contaminating the exposed bottomside surface of the wafer with the filler material (e.g., Cu), which as described above can adversely impact the electrical performance of the IC. Alternative “soft” TSV tip reveal processes cease grinding/polishing prior to reaching the embedded TSV tips, which can reduce filler material (e.g., Cu) contamination of the bottomside surface of the wafer. However, soft reveal processes result in non-optimum tip coplanarity as well as the need to remove more substrate (e.g., Si) during the subsequent TSV tip revelation processing resulting in longer processing times and higher costs as compared to grinding/polishing-based TSV tip revelation.

### SUMMARY

Disclosed embodiments include methods for forming integrated circuits (ICs) having through-substrate vias (TSVs) comprising TSV tips protruding from the bottomside substrate surface. A metal gettering layer (MGL) is included lateral to the TSV tips that has at least one metal gettering agent therein which remove otherwise freely diffusing metal filler (e.g., Cu) to overcome the above-described filler metal contamination problem associated with known mechanical TSV tip reveal processes. Disclosed MGLs allow use of mechanical (grinding and/or polishing) TSV tip reveal processes, while still limiting the grinding/polishing generated contamination on the bottomside surface of the IC die from the filler material (e.g., Cu) described above. Mechanical TSV tip reveal processes enable forming protruding TSV tips which are substantially coplanar and on a plane parallel to the bottomside surface of the IC die, along with shorter processing times and lower costs as compared to soft TSV tip reveal processes. Disclosed embodiments also include ICs obtained from disclosed methods.

### BRIEF DESCRIPTION OF THE DRAWINGS

Reference will now be made to the accompanying drawings, which are not necessarily drawn to scale, wherein:

FIG. 1 is a flow chart that shows steps in an example method for forming an IC including TSVs having protruding TSV tips including mechanical revealing of the TSV tips, forming protruding TSV tips after revealing, and forming a MGL lateral to the protruding TSV tips, according to an example embodiment.

FIGS. 2A-2F are cross-sectional diagrams showing processing progression for the method described relative to FIG. 1.

FIG. 3 is a simplified cross sectional depiction of an IC comprising a plurality of TSVs that have a MGL including at least one metal gettering agent lateral to protruding TSV tips, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

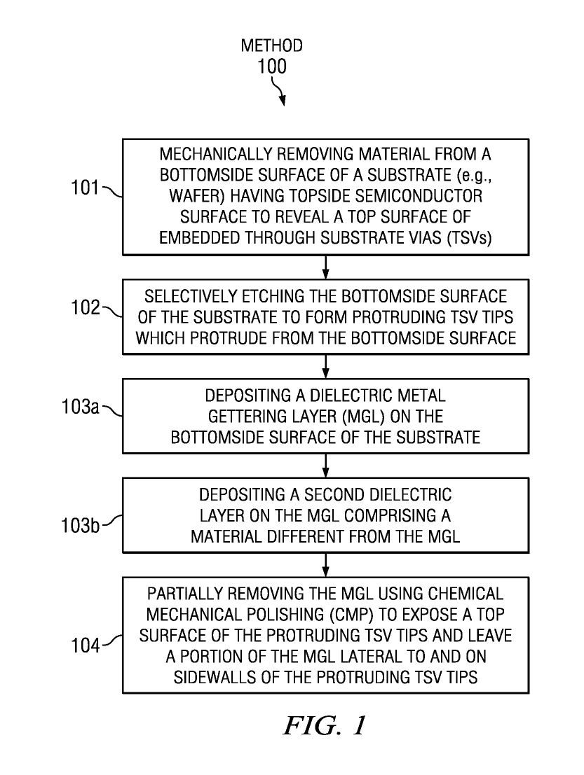

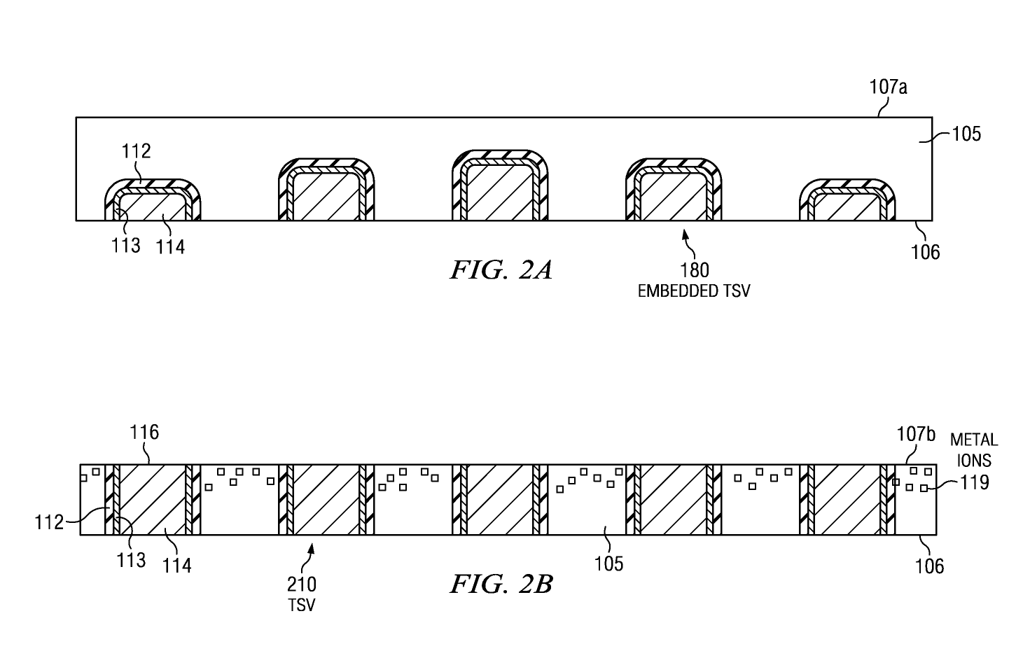

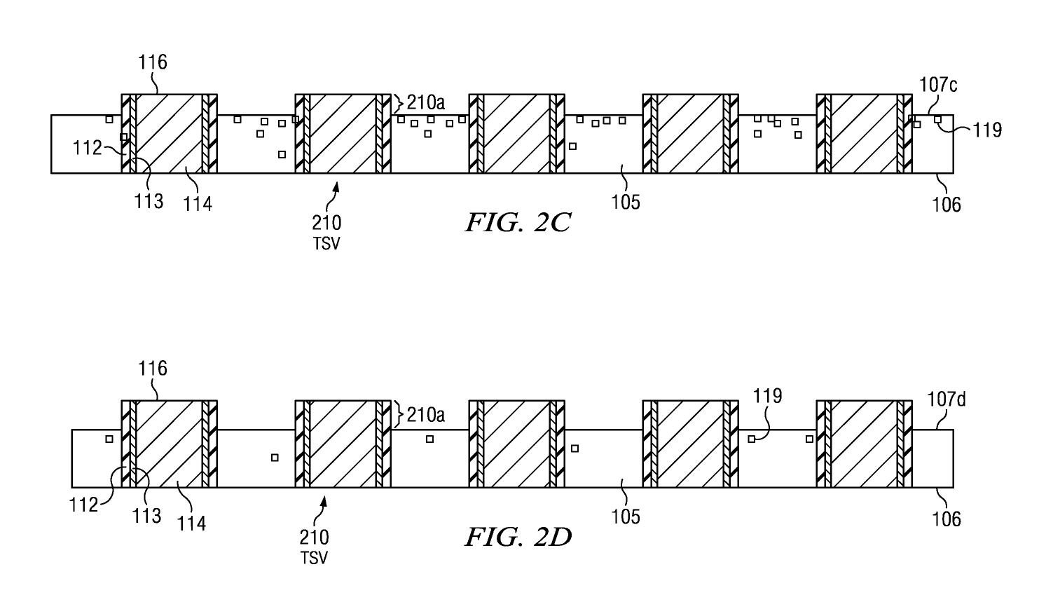

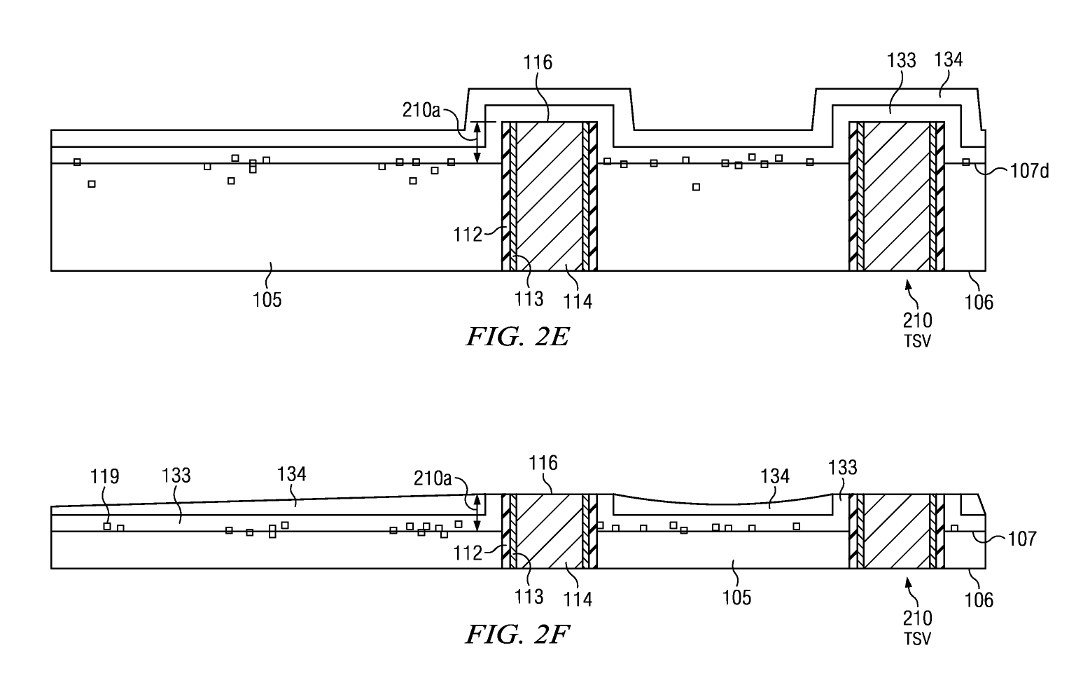

FIG. 1 is a flow chart that shows steps in an example method 100 for forming an IC die having protruding TSV tips including mechanical revealing of TSV tips, forming protruding TSV tips, and forming a MGL layer lateral to the protruding TSV tips, according to an example embodiment. Method 100 is generally applied to wafers comprising a plurality (typically hundreds or thousands) of IC die. FIGS. 2A-2F are cross-sectional diagrams showing an IC die before method 100 in FIG. 2A and processing progression of the die for method 100 in FIGS. 2B-2F.

The IC die in FIG. 2A includes a substrate 105 that may comprise any suitable material, for example, silicon, silicon-germanium, silicon-on-insulator (SOI), or gallium arsenide (GaAs). The IC die may be 300 μm to 800 μm thick before step 101 (mechanical removing), and between 25 μm and 150 μm following step 101. The embedded TSVs 180 each include an outer dielectric liner 112, a metal comprising diffusion barrier layer 113 on the outer dielectric liner 112, and a metal filler (TSV core) 114 on the metal comprising diffusion barrier layer 113.

The metal comprising diffusion barrier layer 113 has a thickness of about at least 4 nm to be sufficient to provide its metal blocking function. The metal comprising diffusion barrier layer 113 can comprise titanium, titanium nitride, tantalum, tantalum nitride, manganese, ruthenium or combinations thereof. The metal comprising diffusion barrier layer 113 is generally refractory metal comprising and can also serve the function of a seed layer for the metal filler 114. For electroplated copper filler material, ruthenium is the only material on the listing above that can act as a seed layer.

The outer dielectric liner 112 frames sidewalls and the bottom of the embedded TSVs 180. The thickness range for the outer dielectric liner 112 is generally 0.1 μ-1 μm. The outer dielectric liner 112 can comprise an oxide, oxynitride, or a polymeric dielectric. In some embodiments the outer dielectric liner 112 can comprise a phosphorus-doped oxide, an arsenic-doped oxide, or a fluorine-doped oxide, such as disclosed in U.S. Pat. No. 7,943,514 to West (one of the Inventors herein).

The aspect ratio (AR) of the embedded TSVs 180 and resulting TSVs having protruding TSV tips is generally from about 5:1 to 20:1, and in one embodiment is <10. In one embodiment the metal filler 114 comprises copper. Embedded TSVs 180 as shown in FIG. 2A can be seen to have a large variance in their height dimension. The height variation depicted in FIG. 2A is intended to depict a possible TSV height variation across a large area wafer, such as a 12 inch wafer. The TSV height variation for adjacent TSVs on a given IC die will generally be only be a small fraction of the TSV height variation across the wafer.

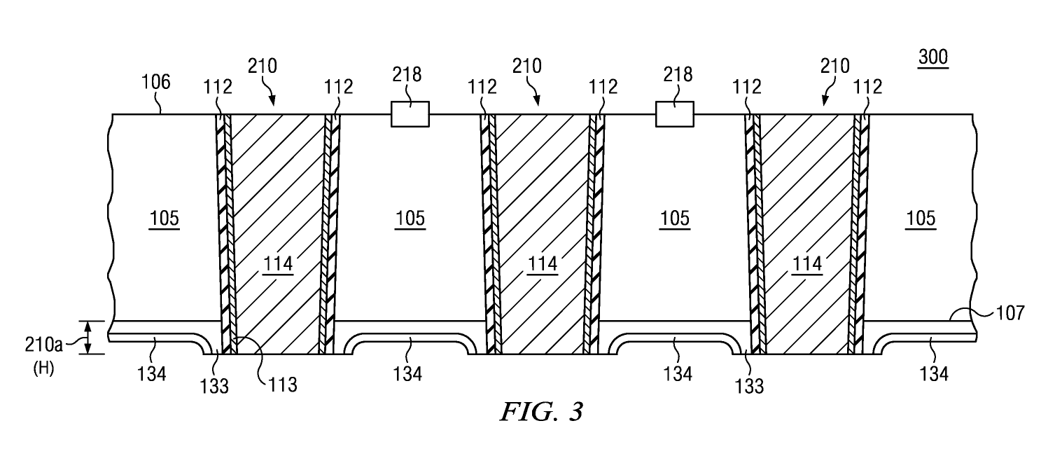

The substrate 105 has a topside semiconductor surface 106 including active circuitry (not shown; see FIG. 3 for active circuitry 218) configured to provide functionality and a bottomside surface 107a. “Functionality” refers to a desired functionality for the IC, such as that of a digital IC (e.g., digital signal processor) or analog IC (e.g., amplifier or power converter), as opposed to a test structure which is not considered to be “functional”. The capability of circuitry to provide the functionality for disclosed ICs may vary, for example ranging from a relatively simple device to a complex device. The specific functionality contained within disclosed ICs is not of importance to disclosed embodiments.

The mechanically removing substrate material in step 101 reveals a distal surface 116 of the previously embedded TSVs 180 shown in FIG. 2B to form TSVs 210 and reach the bottomside surface of the substrate 105 now shown as 107b. Following step 101, the TSVs 210 extend from the topside semiconductor surface 106 to the bottomside surface 107b of the substrate 105. Mechanically removing can comprise backgrinding followed by fine dry polishing or wet Chemical Mechanical Polishing (CMP). Disclosed mechanically removing including TSV tip revealing eliminates the impact of both the incoming total thickness variation as well as the effect of the wafer thinning process non-uniformity, and largely eliminates the across wafer height variation of the TSV tips that results when using known soft revealing processes resulting from the embedded TSV height variation as depicted in FIG. 2A. The distal surface 116 of the TSVs 210 can be seen to be flush (planar) with the bottomside surface 107b at this point in the method. This TSV planarity with the bottomside surface 107b leads subsequently to uniform tip protrusion heights as seen in FIGS. 2C-2E described below.

However, the polishing in step 101 removes portions of the metal filler 114 that can contaminate the exposed bottomside surface 107b of the substrate by either atomic diffusion from the wet fine polishing slurry or, in the case of dry mechanical polishing, by physical smearing of some of the metal filler material (e.g., copper) onto the bottomside surface 107b of the die lateral to the TSVs 210, which can diffuse into the near surface region as shown in FIG. 2B as metal ions 119. Since the presence of the metal ions 119 may be detrimental to the performance of circuit components on the IC, the metal ions 119 are substantially removed through the subsequent steps as described below.

Step 102 comprises selectively etching (relative to the TSV filler, such as copper) the bottomside surface 107b of the substrate 105 to form protruding TSV tips 210a that protrude from resulting bottomside surface 107c of the substrate 105. The TSVs 210 can be seen to be integral structures which extend from the topside semiconductor surface 106 to the distal surface 116 of the TSV tips 210a. In one embodiment a blanket (unmasked) dry etch is followed by a blanket wet etch. The blanket dry etch can uniformly etch 2 μm to 10 μm from the bottomside surface 107b of the substrate 105 to form protruding TSV tips 210a that are 2 μm to 12 μm in height relative to the resulting bottomside surface 107c.

FIG. 2C shows the IC die following selective removal of a layer from the bottomside surface 107b of the IC die with respect to the TSVs 210, resulting in revealing a height of newly formed TSV tips 210a, such as protruding 2 to 10 μm in height, which are generally highly coplanar due to backgrind and fine polishing being highly coplanar, while the TSV tip 210a protrusion uniformity is primarily defined by the bottomside etch uniformity.

The wet etch can remove an additional 0.3 μm to 1.0 μm of material from the bottomside surface 107c. For example, for wet etching silicon, hydroxides such as Tetramethylammonium Hydroxide (TMAH) based chemistries can be used to etch a surface layer from the bottomside surface 107c of the substrate 105 to remove metal ions (e.g., Cu⁺²) in the surface layer. The wet etch generally has minimal impact on TSV tip height 210a variation.

FIG. 2D shows the IC die following an additional selective removal of a layer from the bottomside surface 107c of the IC die with respect to the TSVs 210 to reveal bottomside surface 107d, such as an additional 0.3 to 1.0 μm of material from the bottomside surface 107c which increases the height of TSV tips 210a. The concentration of metal ions 119 in the bottomside surface 107d depicted in FIG. 2D (after wet etch) can be seen to be significantly less as compared to the concentration of metal ions 119 in the bottomside surface 107c as shown in FIG. 2C (before wet etch).

Step 103a comprises depositing a dielectric MGL 133 on the bottomside surface 107d of the substrate 105. Step 103b comprises optionally depositing a second dielectric layer 134 on the MGL 133 comprising a material different from the MGL 133. FIG. 2E shows the IC die following steps 103a and 103b having a dielectric MGL 133 on the bottomside surface 107d of the substrate 105 lateral to and on sidewalls of the protruding TSV tips 210a, and an optional second dielectric layer 134 on the MGL 133 comprising a material different from the MGL 133.

Disclosed MGLs 133 can be contrasted with known TSV tip processing methods which use undoped dielectrics, such as an undoped silicon oxide or silicon nitride. The MGL 133 includes at least one metal gettering agent comprising a halogen or a Group 15 element (“pnictogens,” formerly numbered as Group V or Group VA), such as phosphorus, arsenic, or antimony) in an average total gettering agent concentration from 0.1 to 10 atomic %. The metal gettering agent in the MGL 133 getters, or captures, metal ions near the bottomside surface 107d of the substrate 105 and renders them immobile and thus no longer potentially problematic for IC functionality and performance (e.g., leakage).

One example MGL 133 comprises phosphorus doped silicon glass (PSG). During subsequent process steps, some of which are at elevated temperature (such as 200° C. to 270° C. for Thermo-compression (TC) bonding), MGL material such as PSG effectively getters metal ions near the bottomside surface 107d that were initially incorporated into the bottomside surface 107b of the substrate 105 during tip reveal, or into bottomside surface 107c during silicon etch processing, rendering them immobile. The material for the second dielectric layer 134 can comprise silicon nitride or silicon oxynitride.

The metal gettering agent is generally in an anionic state (e.g., is oxidized) while within the MGL 133, so that the metal gettering agent has a significant local negative charge when present in the MGL. Concentrations above approximately 5 to 10 atomic % for most metal gettering agents can trigger undesirable segregation of the metal gettering agent, such as formation of P₂O₅ crystals for silicon oxide dielectrics at a level from about 6 to 7.9 atomic % phosphorus, or potentially harmful unbound fluorine for fluorine embodiments when the fluorine level exceeds about 5 atomic %. Accordingly, the concentration of the metal gettering agent is generally from 1 to 5 atomic %. The MGL 133 together with its metal gettering agent(s) can be deposited in-situ.

Although not seeking to be bound by theory, with the theory not necessary to practice disclosed embodiments, Applicants provide a theory to explain the efficacy of disclosed embodiments that also helps define operable metal gettering agents and metal gettering agents in MGLs are those that support significant local negative charge of the metal gettering agent which represents favorable sites for attracting and trapping highly mobile positive ions. As described above, copper exists as a cation and is highly mobile in semiconductors such as silicon, and in dielectric materials such as silicon dioxide, and as a result of copper contamination during wet mechanical polishing or smearing during backgrinding or dry polishing described above can result in the metal filler 114 diffusing into the bottomside of the semiconductor (e.g., silicon) to reach active circuitry on the topside semiconductor surface 106. Without the metal gettering dielectric MGLs 133 disclosed herein, highly mobile positive ions such as copper can otherwise diffuse to the topside semiconductor surface 106 to reach active circuitry and compromise IC performance, or even functionality.

In one particular embodiment, the MGL 133 is a low-temperature (e.g., <250° C.) deposited 0.3 to 0.7 μm PSG layer having a 1 μm to 3 μm silicon nitride (SiN) layer thereon to provide a bilayer dielectric film. The SiN layer acts as passivation layer; and the PSG has gettering characteristics to capture ionic contamination from the underlying Si. Any subsequent processing that causes “doming” of the wafer or die will tend to preferentially drive interstitial metal ions (e.g., Cu ions) through the substrate towards the gettering PSG layer or other suitable MGL 133. The silicon nitride film provides a diffusion block against subsequent bottomside contamination and has the additional benefit of providing a die bottomside surface that for die-to die assembled devices is likely to match the surface of the other die, presenting a favorable scenario for engineering the die adhesive properties.

Step 104 comprises partially removing the MGL 133 using CMP to re-expose a distal surface 116 of the protruding TSV tips 210a and leave a portion of the MGL 133 lateral to and on sidewalls of the protruding TSV tips 210a. FIG. 2F described below shows the IC die following partially removing the MGL 133 and optional second dielectric layer 134 on the MGL 133 using CMP. Partially removing the MGL 133 and optional second dielectric layer 134 with CMP to reveal the TSV tips a second time leaves non-zero dielectric second dielectric layer 134/MGL 133 on the bottomside surface 107d of the substrate 105 in the non-tip (lateral) regions. The exposed distal surface 116 again reveals the metal filler 114 of the TSVs 210 which facilitates the formation of subsequent assembly processing including metallurgical and electrical connections to other components of a semiconductor package, such as to a second semiconductor chip or a package substrate.

Enhanced CMP dielectric removal rate at the TSV tip 210a regions results from increased pressure (p) in these regions, as shown in Preston's Equation, below:

$$\frac{d z}{d t} = - {k}_{p} pv$$

In Preston's Equation above, p is pad pressure or force per unit area applied to the wafer, v is the relative velocity of the wafer relative to the pad, and dz/dt=r is the rate of material removed (cutting depth per unit time). The constant, k, is known as the Preston coefficient. This coefficient reflects the type of lap, the type of material, the type of grit, etc. Preston's Equation means that the rate of CMP surface removal (or weight loss) increases as the downward force increases or if the velocity increases.

As noted above, including a disclosed MGL 133, such as a PSG MGL, for IC devices having TSVs including TSV tips allows backgrinding and polishing to reveal TSV tips to reset within-die coplanarity of TSV tips, while also limiting TSV filler metal contamination. Comparing to other known approaches for forming IC devices having TSVs including TSV tips that limit TSV filler metal contamination, such as the soft reveal approach described in the Background above, usually stop grinding/polishing prior to reaching the TSV tips, and use a substrate (e.g., Si) etch back to reveal the TSV tips, thereby inheriting any pre-existing undesirable non-uniformity in TSV depths, and are thus susceptible to significant across the die and across the wafer variation in tip height. As known in the art, TSV tips in a wafer being out of coplanarity is a major obstacle in advancing TSV packaging into mass production for die having protruding TSV tips. Significantly, ICs having TSVs with highly co-planar TSV tips enabled by grinding/polishing TSV tip revealing that overcome filler material contamination concerns associated with grinding/polishing TSV tip revealing enables formation of stacked 3-D semiconductor packages with high reliability and high manufacturing throughput. Another advantage vs. known methods is that if there is a filler material leak through a defect in the barrier metal somewhere within the substrate, disclosed MGLs will help getter that source of contamination as well.

FIG. 3 is a simplified cross sectional depiction of an IC 300 comprising a plurality of TSVs 210 that have a MGL 133 and optional second dielectric layer 134 lateral to the protruding TSV tips 210a including at least one metal gettering agent, according to an example embodiment. The protruding TSV tips 210a are shown having a tip height (H). H is generally 2.0 μm to 12 μm in height, but can be outside this range.

The TSVs 210 include an outer dielectric liner 112, a metal comprising diffusion barrier layer 113 on the outer dielectric liner 112, and a metal filler 114 on the metal comprising diffusion barrier layer 113. The outer dielectric liner 112 generally comprises silicon oxide or silicon oxynitride that can be seen to be framing the TSVs 210 within substrate 105. The metal filler 114 can comprise copper in one embodiment. Metal filler 114 substantially fills the TSVs 210. “Substantially fills” is meant to include the case of electroplated metals such as copper, wherein a center seam or void region on the order of about 1 μm can exist with the metal filler 214.

Contact, metallization levels and passivation overcoat on the IC 300 are omitted for clarity. IC 300 comprises a substrate 105 including a topside semiconductor surface 106 and a bottomside surface 107, wherein the topside semiconductor surface 106 includes one or more instances of active circuitry 218 (e.g., MOS transistors) and passive components (resistors, capacitors) configured to provide circuit functionality. The substrate 105 has a thickness that is typically 50 to 100 μm following above described mechanical substrate removing (step 101), but can generally range between 5 μm and 200 μm in thickness.

Although the dielectric liner 112 is shown extending the full TSV tip height H, the height of the dielectric liner 112 can be 10 to 100% of the tip height H, and is generally <100% to provide an exposed tip portion for making electrical connection to an underlying workpiece. Although not shown, the TSVs 210 can include a surface finish such as electroless Ni/Pd or electroless Ni/Au with an outer surface of a readily solder wettable metal such as Pd or Au. Alternately, a functionally equivalent metal pad may be formed electrolytically to provide both a diffusion barrier, such as Ni, between metal filler 114 and subsequently applied solder, as well as to provide an outer surface of readily solder wettable metal such as Pd or Au.

Disclosed embodiments can be integrated into a variety of assembly flows to form a variety of different semiconductor IC devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. An integrated circuit (IC), comprising:
a substrate having a topside semiconductor surface including active circuitry configured to provide functionality and a bottomside surface;
a plurality of through substrate vias (TSVs) extending from said topside semiconductor surface to beyond said bottomside surface to provide protruding TSV tips, said plurality of TSVs each including an outer dielectric liner, a metal comprising diffusion barrier layer on said dielectric liner, and a metal filler on said metal comprising barrier layer, and
a dielectric metal gettering layer (MGL) on said bottomside surface lateral to and on sidewalls of said protruding TSV tips, said MGL including at least one metal gettering agent comprising a halogen or a Group 15 element in an average concentration from 0.1 to 10 atomic %.

2. The IC of claim 1, wherein said MGL comprises a phosphorus-doped oxide, an arsenic-doped oxide, or a fluorine-doped oxide.

3. The IC of claim 1, wherein said topside semiconductor surface comprises silicon and said metal filler comprises copper.

4. The IC of claim 1, wherein an aspect ratio (AR) of said plurality of TSVs is <10.

5. The IC of claim 1, further comprising a second dielectric layer on said MGL comprising a material different from said MGL.

6. The IC of claim 5, wherein said second dielectric layer comprises silicon nitride.

7. The IC of claim 1, wherein said metal comprising diffusion barrier layer comprises titanium, titanium nitride, tantalum, tantalum nitride, manganese, ruthenium, or combinations thereof.

8. The IC of claim 1, wherein said bottomside surface is a silicon surface.

9. An integrated circuit (IC), comprising:
a substrate having a topside silicon surface including active circuitry configured to provide functionality and a bottomside silicon surface;
a plurality of through substrate vias (TSVs) extending from said topside semiconductor surface to beyond said bottomside silicon surface to provide protruding TSV tips, said plurality of TSVs each including an outer dielectric liner, a metal comprising diffusion barrier layer on said dielectric liner, and a copper filler on said metal comprising barrier layer;
a dielectric metal gettering layer (MGL) on said bottomside silicon surface lateral to and on sidewalls of said protruding TSV tips, said MGL including at least one metal gettering agent comprising phosphorous in an average concentration from 0.1 to 10 atomic %, and
a second dielectric layer on said MGL comprising a material different from said MGL.

10. The IC of claim 9, wherein said second dielectric layer comprises silicon nitride and said MGL comprises a phosphorus-doped oxide.

11. A method of forming an integrated circuit (IC), comprising:
mechanically removing material from a bottomside surface of a substrate having a topside semiconductor surface to expose embedded through substrate vias (TSVs) which extend from said topside semiconductor surface to said bottomside surface, said TSVs each including an outer dielectric liner, a metal comprising diffusion barrier layer on said dielectric liner, and a metal filler on said metal comprising barrier layer,
etching said bottomside surface to form protruding TSV tips that protrude from said bottomside surface;
depositing a dielectric metal gettering layer (MGL) on said bottomside surface, said MGL including at least one metal gettering agent comprising a halogen or a Group 15 element in an average concentration from 0.1 to 10 atomic %, and
partially removing said MGL using Chemical Mechanical Polishing (CMP) to reveal a distal surface of said protruding TSV tips and leave a portion of said MGL lateral to and on sidewalls of said protruding TSV tips.

12. The method of claim 11, further comprising depositing a second dielectric layer on said MGL comprising a material different from said MGL before said partially removing.

13. The method of claim 12, wherein said second dielectric layer comprise silicon nitride.

14. The method of claim 11, wherein said MGL comprises a phosphorus-doped oxide, an arsenic-doped oxide, or a fluorine-doped oxide.

15. The method of claim 11, wherein said topside semiconductor surface comprises silicon and said metal filler comprises copper.

16. The method of claim 11, wherein said etching comprises a dry etch followed by a wet etch.

17. The method of claim 11, wherein an aspect ratio (AR) of said plurality of TSVs is <10.
